(19) United States
(12) Patent Application Publication
(10) Pub. No.: US 2024/0429302 A1
(43) Pub. Date: Dec. 26, 2024

(54) MEMORY DEVICE AND FORMING METHOD THEREOF

(71) Applicant: NANYA TECHNOLOGY CORPORATION, New Taipei City (TW)

(72) Inventors: Yu-Ping CHEN, New Taipei City (TW); Chung-hsun HUANG, Taoyuan City (TW)

(21) Appl. No.: 18/211,655

(22) Filed: Jun. 20, 2023

(51) Int. Cl. H01L 29/45; H01L 29/40

(52) U.S. Cl. CPC H01L 29/45; H01L 29/401

(57) ABSTRACT

The present disclosure provides a memory device and the forming method thereof. The memory device includes a gate structure on a substrate, a source/drain region in a substrate, a dielectric layer covering the substrate and the gate structure, and a cell contact adjacent to the gate structure. The cell contact includes a conductive layer, a first barrier layer on a sidewall of the conductive layer, and a second barrier layer on a bottom surface of the conductive layer. The second barrier layer directly contacts the first barrier layer and the source/drain region. A second resistivity of the second barrier layer is lower than a first resistivity of the first barrier layer.

### BACKGROUND

### Field of Invention

The present disclosure relates to the memory device and the forming method thereof. More particularly, the present disclosure relates to the memory device having the cell contact.

### Description of Related Art

As the critical dimension (CD) of the features in the memory device becomes smaller, the size of the memory device is correspondingly reduced, thereby increasing the element density in one device. However, the reduced sizes of the features bring higher difficulty in manufacturing, which may easily cause the defects in the memory device. For example, it becomes harder to uniformly form the cell contact between the compact elements, leading to the seam in the cell contact and lower reliability of the device. Therefore, an approach to form the cell contact with a complete structure is required for the formation of the memory device.

### SUMMARY

According to one embodiment of the present disclosure, a memory device includes a gate structure on a substrate, a source/drain region in the substrate, a dielectric layer covering the substrate and the gate structure, and a cell contact adjacent to the gate structure. The cell contact includes a conductive layer, a first barrier layer on a sidewall of the conductive layer, and a second barrier layer on a bottom surface of the conductive layer. The second barrier layer directly contacts the first barrier layer and the source/drain region, and a second resistivity of the second barrier layer is lower than a first resistivity of the first barrier layer.

In some embodiments, the first barrier layer and the second barrier layer collectively surround the conductive layer to separate the conductive layer from the dielectric layer and the substrate.

In some embodiments, a first compactness of the first barrier layer is higher than a second compactness of the second barrier layer.

In some embodiments, a first thickness of the first barrier layer is equal to a second thickness of the second barrier layer.

In some embodiments, a first thickness of the first barrier layer is smaller than or equal to 20 nm.

In some embodiments, the first barrier layer and the second barrier layer include a same composition.

In some embodiments, the first barrier layer includes TiN, SiN, SiO₂, or combinations thereof.

In some embodiments, the memory device further includes a third barrier layer on a top surface of the dielectric layer. The conductive layer extends onto the third barrier layer, and a third resistivity of the third barrier layer is lower than the first resistivity of the first barrier layer.

In some embodiments, the third barrier layer directly contacts the first barrier layer.

In some embodiments, a side surface of the third barrier layer is coplanar with a side surface of the first barrier layer.

In some embodiments, the third resistivity of the third barrier layer is equal to the second resistivity of the second barrier layer.

In some embodiments, the first barrier layer extends into the source/drain region, and the second barrier layer is lower than a top surface of the substrate.

In some embodiments, the first barrier layer includes a material different from that of the dielectric layer.

According to one embodiment of the present disclosure, a method of forming a memory device includes the following steps. A gate structure on a substrate and a dielectric layer covering the gate structure are provided. An opening is formed through the dielectric layer, in which the opening exposes a source/drain region in the substrate. A first barrier layer is deposited in the opening and on the dielectric layer by a first process. A first portion of the first barrier layer on a bottom surface of the opening is removed, and a second portion of the first barrier layer is remained on a side surface of the opening. A second barrier layer is deposited on the bottom surface of the opening by a second process, in which the second barrier layer has a second resistivity different from a first resistivity of the first barrier layer. A conductive layer is formed in the opening.

In some embodiments, the first process is advanced sequential flow deposition, and the second process is chemical vapor deposition.

In some embodiments, the first barrier layer deposited by the first process has a first compactness different from a second compactness of the second barrier layer deposited by the second process.

In some embodiments, removing the first barrier layer further includes removing a third portion of the first barrier layer on a top surface of the dielectric layer.

In some embodiments, depositing the second barrier layer on the bottom surface of the opening includes directly depositing the second barrier layer onto the source/drain region exposed by the opening.

In some embodiments, after depositing the second barrier layer, the first barrier layer and the second barrier layer collectively cover the side surface and the bottom surface of the opening.

In some embodiments, after depositing the second barrier layer, the first barrier layer is exposed in the opening.

According to the above-mentioned embodiments, the cell contact of the memory device includes a first barrier layer and a second barrier formed by different processes. The first barrier layer and the second barrier layer cover the surface of the opening for the conductive layer, so that the conductive layer fills the opening without forming the seal inside. The second barrier layer reduces the resistivity between the cell contact and the source/drain region.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a method flow diagram of forming a memory device according to some embodiments of the present disclosure.

FIGS. 2A to 2F illustrate cross-sectional views of a memory device at various intermediate stages of a forming process according to some embodiments of the present disclosure.

### DETAILED DESCRIPTION

The following disclosure provides many different embodiments, or examples, for implementing different features of the provided subject matter. Specific examples of components, arrangements, etc., are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure provides a memory device including a cell contact adjacent to the gate structure to electrically connect the source/drain region. The cell contact includes a conductive layer, a first barrier layer formed by a first process, and a second barrier layer formed by a second process. The first barrier layer and the second barrier layer continuously covers the opening for filling the conductive layer, so that the conductive layer is uniformly filled without missing material and forming a seal in the cell contact. The second barrier layer with lower resistivity is formed between the conductive layer and the source/drain region to reduce the resistivity of the conductive path.

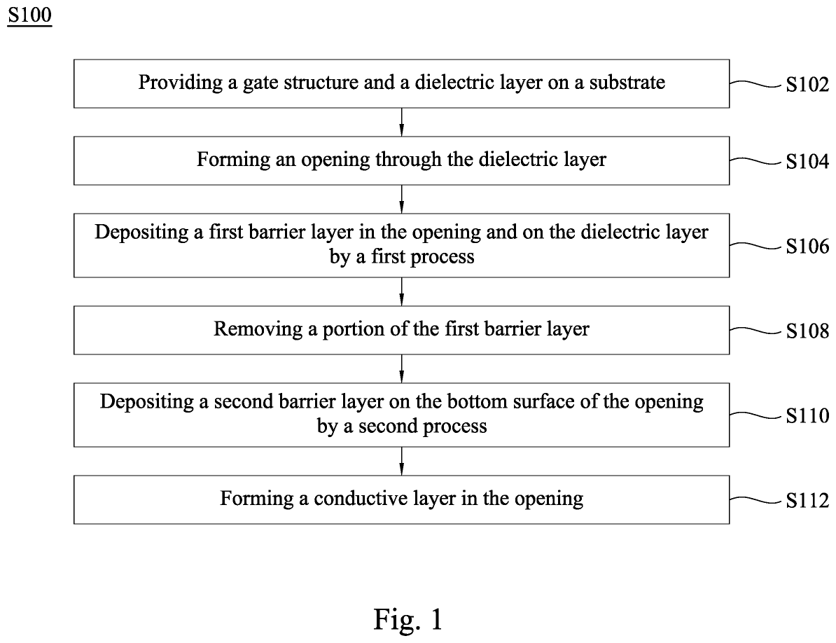

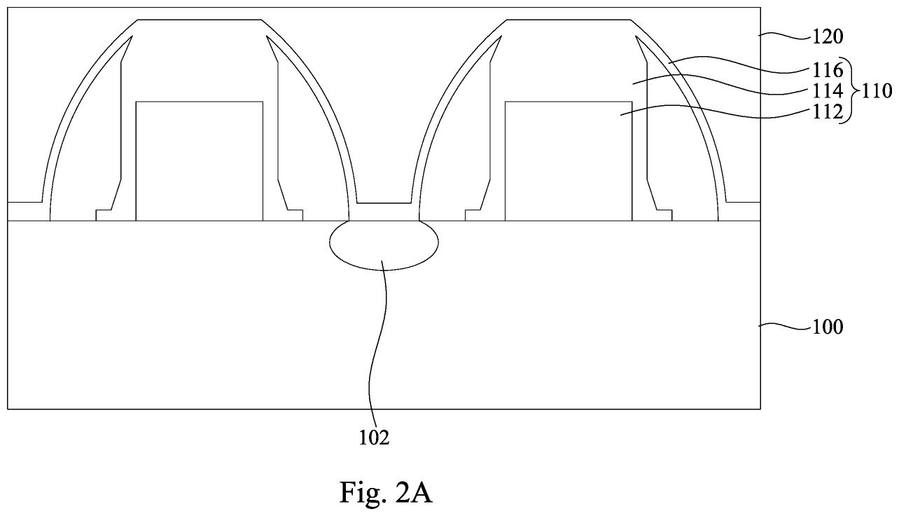

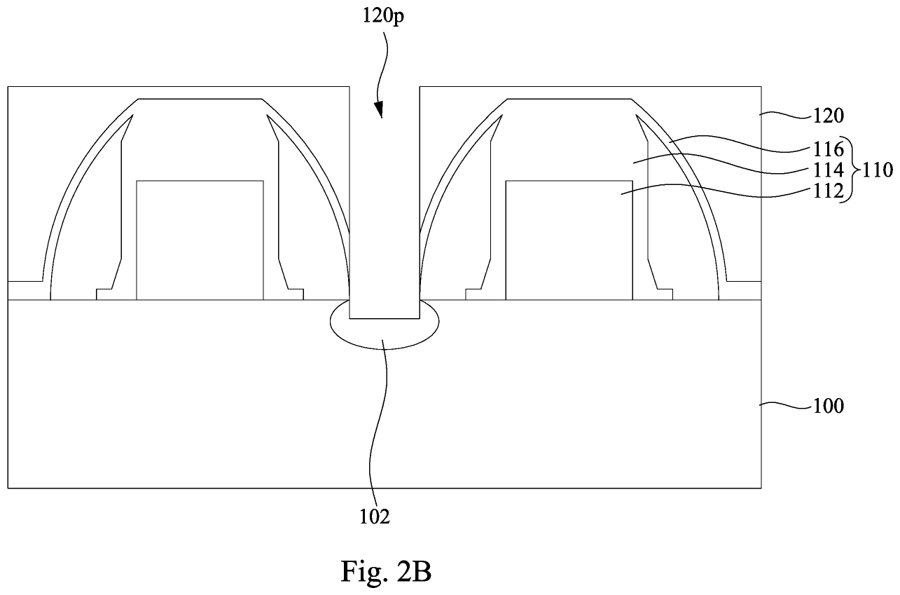

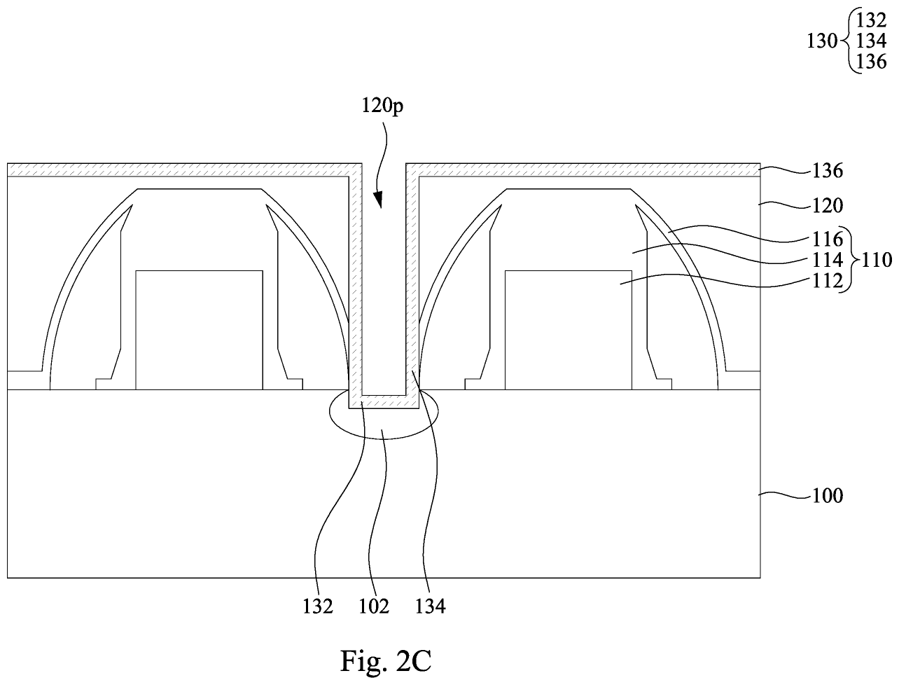

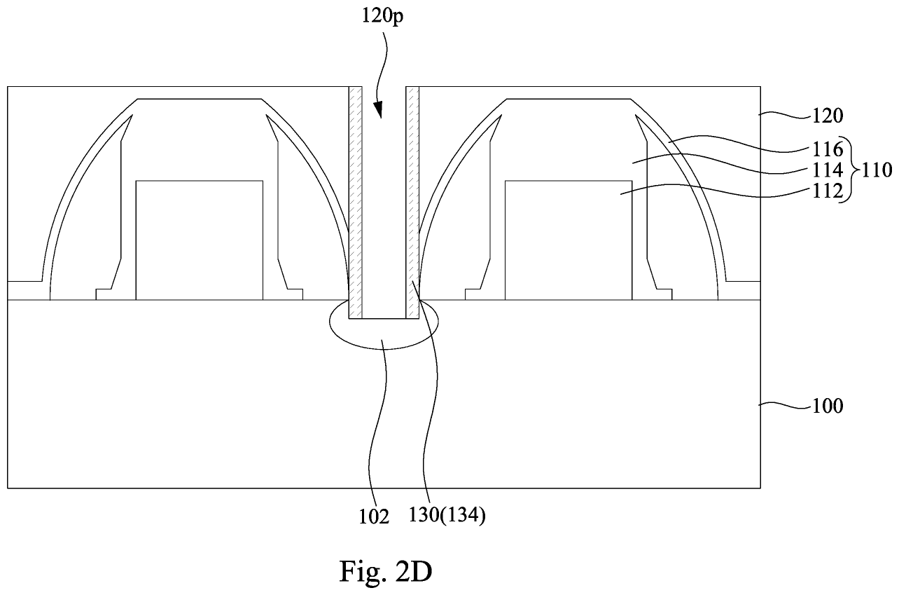

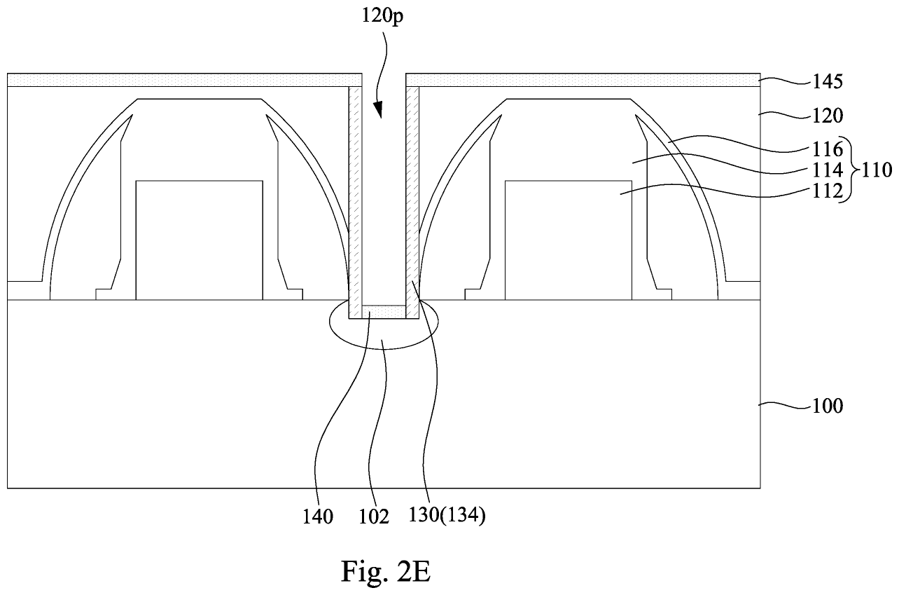

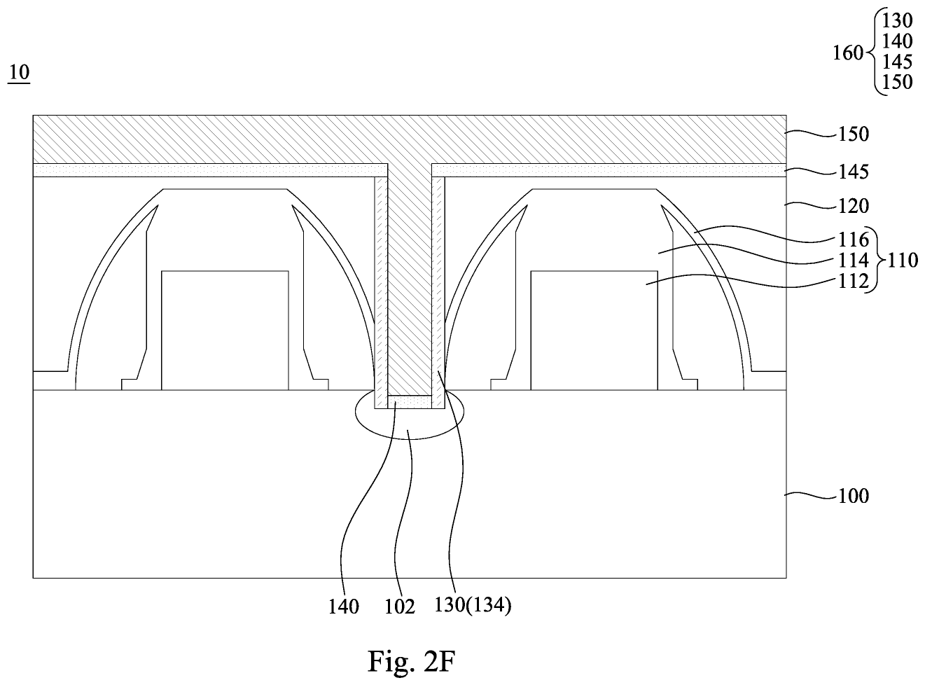

According to some embodiments of the present disclosure, FIG. 1 illustrates a flow diagram of method S100 of forming a memory device. FIGS. 2A to 2F illustrate cross-sectional views of a memory device at various intermediate stages of the forming method S100 in FIG. 1. The manufacturing of the memory device 10 shown in FIG. 2F is taken as an example to depict the forming method S100. However, those skilled in the art should understand that the method shown in FIG. 1 and FIGS. 2A to 2F can not only be used to form the memory device 10, but also can be used to form other memory devices having the cell contact within the scope of the present disclosure.

Referring to FIG. 1 and FIG. 2A, the method S100 starts from step S102, where a gate structure 110 and a dielectric layer 120 on a substrate 100 are provided. The top surface of the dielectric layer 120 is higher than those of the gate structure 110 and the substrate 100, so that the dielectric layer 120 covers the gate structure 110 and the substrate 100. As shown in FIG. 2A, the dielectric layer 120 may cover at least two gate structures 110 on the substrate 100 for the following formation of the cell contact between the gate structures 110. However, the number of the gate structures 110 covered by the dielectric layer 120 may be various according to the requirement of the device.

In some embodiments, the substrate 100 may be a semiconductor substrate, such as bulk semiconductor, semiconductor-on-insulator (SOI), or the like. The substrate 100 may include silicon, silicon carbide, silicide, doped silicon, or other material suitable for forming a source/drain region 102 inside. In some embodiments, the dielectric layer 120 on the substrate 100 may include silicon oxide, high-k dielectric material, or the like.

In some embodiments, the gate structure 110 adjacent to the source/drain region 102 may include a gate electrode 112 on the substrate 100 and a gate dielectric layer 114 covering the gate electrode 112. The gate electrode 112 may include metal, metal silicide, polysilicon, or other suitable conductive materials. The gate dielectric layer 114 may be made of a material different from that of the dielectric layer 120, such as nitrides. The gate structure 110 may further include a supporting leg 116 extended from the gate dielectric layer 114. The supporting leg 116 helps to stabilize the gate structure 110 on the substrate 100. The dielectric layer 120 may be formed between the supporting leg 116 and the gate dielectric layer 114.

Referring to FIG. 1 and FIG. 2B, the method S100 proceeds to step S104, where an opening 120p is formed through the dielectric layer 120. Specifically, the opening 120p is formed from the top surface of the dielectric layer 120 toward the substrate 100. The opening 120p is adjacent to the gate structure 110 to expose the substrate 100 on a side of the gate structure 110. The opening 120p defines the position of the following formed cell contact, so that the opening 120p may especially expose the source/drain region 102 in the substrate 100. Although the opening 120p is illustrated as having a flat bottom surface, the opening 120p in other embodiments may have a curved bottom surface.

In the embodiments which the dielectric layer 120 covers a plurality of gate structures 110, the opening 120p may be formed between two of the gate structures 110. In some embodiments, the opening 120p may extend into the source/drain region 102. As shown in FIG. 2B, the opening 120p may extend until the bottom surface of the opening 120p is lower than the top surface of the substrate 100. In such embodiments, a portion of the source/drain region 102 may be removed for the opening 120p. In some other embodiments, the depth of the opening 120p may be equal to the dielectric layer 120, so that the surface of the source/drain region 102 exposed in the opening 120p is basically coplanar with the top surface of the substrate 100.

Referring to FIG. 1 and FIG. 2C, the method S100 proceeds to step S106, where a first barrier layer 130 is deposited in the opening 120p and on the dielectric layer 120. Specifically, the first barrier layer 130 is deposited by a first process suitable for depositing the material in the opening 120p with high aspect ratio. For example, the first barrier layer 130 may be deposited by an advanced sequential flow deposition (ASFD). Advanced sequential flow deposition is a technique similar to the atomic layer deposition (ALD) process. The material deposited by one reaction cycle of the advanced sequential flow deposition has a thickness in atomic-scale, which provides the deposited material with high conformity. As a result, the first barrier layer 130 may continuously and conformally cover the opening 120p and the dielectric layer 120. Since the first barrier layer 130 deposited by one reaction cycle of the advanced sequential flow deposition has such thin thickness, the first barrier layer 130 may show higher uniformity and higher compactness than a material layer deposited by chemical vapor deposition (CVD).

As shown in FIG. 2C, after the first process, the first barrier layer 130 includes a first portion 132 covering the bottom surface of the opening 120p, a second portion 134 covering the side surface of the opening 120p, and a third portion 136 covering the top surface of the dielectric layer 120. The first portion 132 and the second portion 134 continuously cover the exposed surface in the opening 120p shown in FIG. 2B. In the embodiments which the bottom surface of the opening 120p is lower than the top surface of the substrate 100, the first portion 132 may be lower than the top surface of the substrate 100.

In some embodiments, a thickness of the first barrier layer 130 may be sufficient to cover the surface of the opening 120p, while the opening 120p is not entirely filled by the first barrier layer 130. For example, the thickness of the first barrier layer 130 may be larger than 0 nm, while the thickness may be smaller than or equal to 20 nm. If the thickness of the first barrier layer 130 is too close to 0 nm, the first barrier layer 130 may be too thin to uniformly cover the surface exposed in the opening 120p. If the thickness of the first barrier layer 130 is larger than 20 nm, the first barrier layer 130 may affect the following deposition of the second barrier layer 140 shown in FIG. 2E or may significantly change the characteristic of the memory device, such as resistivity.

In some embodiments, the first barrier layer 130 may include TiN, SiN, SiO₂, nitrides formed by decoupled plasma nitridation (DPN) or remote plasma nitridation (RPN), or combinations thereof. The first barrier layer 130 may include a material different from that of the dielectric layer 120, so that the following etching of the first barrier layer 130 may not significantly affect the dielectric layer 120.

Referring to FIG. 1 and FIG. 2D, the method S100 proceeds to step S108, where a portion of the first barrier layer 130 is removed from the structure shown in FIG. 2C. Specifically, the removing process selectively removes the first barrier layer 130 which is parallel to the bottom surface of the opening 120p. For example, the removing process may be an anisotropic etching process, such as the dry etching process using plasma. Therefore, the first portion 132 of the first barrier layer 130 on the bottom surface of the opening 120p is removed, and the second portion 134 is remained on a side surface of the opening 120p. Since the first portion 132 is removed, the source/drain region 102 is re-exposed in the opening 120p.

After removing the first portion 132, the second portion 134 of the first barrier layer 130 may remain on the side surface from top to bottom of the opening 120p. Therefore, in the embodiments which the bottom surface of the opening 120p is lower than the top surface of the substrate 100, the second portion 134 may extend into the source/drain region 102. In some embodiments, removing the first barrier layer 130 may further include removing the third portion 136 on the top surface of the dielectric layer 120. After removing the third portion 136, the top surface of the second portion 134 may be coplanar with the top surface of the dielectric layer 120.

Referring to FIG. 1 and FIG. 2E, the method S100 proceeds to step S110, where a second barrier layer 140 is deposited on the bottom surface of the opening 120p. The second barrier layer 140 is directly deposited onto the source/drain region 102 exposed by the opening 120p, so that the second barrier layer 140 directly contacts the source/drain region 102. In addition, the second barrier layer 140 extends on the bottom surface of the opening 120p to directly contact the first barrier layer 130 on the side surface of the opening 120p. The first barrier layer 130 and the second barrier layer 140 collectively cover the side surface and the bottom surface of the opening 120p after depositing the second barrier layer 140. In the embodiments which the bottom surface of the opening 120p is lower than the top surface of the substrate 100, the second barrier layer 140 may be lower than the top surface of the substrate 100.

Specifically, the second barrier layer 140 is deposited by a second process different from the first process of depositing the first barrier layer 130. The deposition conformity of the first process may be higher than that of the second process. Therefore, some characteristics of the second barrier layer 140 are different from those of the first barrier layer 130. Particularly, the second barrier layer 140 has a second compactness and a second resistivity different from a first compactness and a first resistivity of the first barrier layer 130.

For example, in the embodiments which the first barrier layer 130 is deposited by advanced sequential flow deposition and the second process is deposited by chemical vapor deposition, the second resistivity of the second barrier layer 140 may be lower than the first resistivity of the first barrier layer 130. In such embodiments, the first compactness of the first barrier layer 130 may be higher than the second compactness of the second barrier layer 140.

In some embodiments, the second process may be not suitable as the first process to deposit material on the side surface of the opening 120p, so the second barrier layer 140 is basically formed along the direction parallel to the bottom surface of the opening 120p. As shown in FIG. 2E, the second barrier layer 140 is formed on the bottom surface of the opening 120p, which exposes the first barrier layer 130 in the opening 120p. In some other embodiments, while the surface of the opening 120p is covered by the first barrier layer 130 and the second barrier layer 140, the second barrier layer 140 may cover a portion of the first barrier layer 130.

In some embodiments, the second barrier layer 140 may be formed with a thickness sufficient to cover the bottom surface of the opening 120p, while the opening 120p is not entirely filled by the second barrier layer 140. For example, the first thickness of the first barrier layer 130 may be equal to the second thickness of the second barrier layer 140. In some embodiments, the first barrier layer 130 and the second barrier layer 140 may include a similar or same composition to provide high adhesion between the two barrier layers. This helps the first barrier layer 130 and the second barrier layer 140 to continuously cover the surface of the opening 120p. Although the first barrier layer 130 and the second barrier layer 140 may be formed by the same composition, the first barrier layer 130 and the second barrier layer 140 still show different characteristics due to the difference between the first process and the second process.

In some embodiments, while forming the second barrier layer 140, a third barrier layer 145 may be simultaneously deposited on the top surface of the dielectric layer 120. The third barrier layer 145 extends on the dielectric layer to directly contact the first barrier layer 130. As a result, the first barrier layer 130, the second barrier layer 140, and the third barrier layer 145 collectively cover the opening 120p and the dielectric layer 120. As shown in FIG. 2E, the third barrier layer 145 may extend on the first barrier layer 130 to form the side surface coplanar with the side surface of the first barrier layer 130. Since the third barrier layer 145 is formed in the second process, the characteristic of the third barrier layer 145 may be similar to that of the second barrier layer 140. For example, the third resistivity of the third barrier layer 145 may be equal to the second resistivity of the second barrier layer 140 and lower than the first resistivity of the first barrier layer 130.

Referring to FIG. 1 and FIG. 2F, the method S100 proceeds to step S112, where a conductive layer 150 is formed in the opening 120p. Specifically, the conductive layer 150 is formed on the first barrier layer 130 and the second barrier layer 140 to fill the opening 120p. As the first barrier layer 130 and the second barrier layer 140 continuously cover the surface of the opening 120p, the material of the conductive layer 150 may be uniformly formed from the bottom surface and the side surface of the opening 120p. Therefore, the conductive layer 150 may completely fill the opening 120p without forming the seal in the conductive layer 150.

In some embodiments, the conductive layer 150 may include a single layer or multilayers of metal, such as Ti, W, Cu, Al, or Co, metal silicide, metal nitride, or combinations thereof. In the embodiments which the third barrier layer 145 is formed on the top surface of the dielectric layer 120, the conductive layer 150 may extend onto the third barrier layer 145 and further extend right above the gate structure 110.

Therefore, the memory device 10 is formed. The memory device 10 includes the gate structure 110 on the substrate 100, the source/drain region 102 in the substrate 100, the dielectric layer 120 covering the substrate 100 and the gate structure 110, and a cell contact 160 adjacent to the gate structure 110. The cell contact 160 includes the conductive layer 150, the first barrier layer 130 on the sidewall of the conductive layer 150, and the second barrier layer 140 on the bottom surface of the conductive layer 150. The second barrier layer 140 directly contacts the first barrier layer 130, so that the first barrier layer 130 and the second barrier layer 140 collectively surround the conductive layer 150 to separate the conductive layer 150 from the dielectric layer 120 and the substrate 100. The second barrier layer 140 with lower resistivity is interposed between the conductive layer 150 and the source/drain region 102, so that the conductive path from the conductive layer 150 to the source/drain region 102 has sufficiently low resistivity. The cell contact 160 may further include the third barrier layer 145 between the top surface of the dielectric layer 120 and the conductive layer 150.

According to the above-mentioned embodiments, the memory device formed by the process of the present disclosure includes the cell contact adjacent to the gate structure. The cell contact includes a first barrier layer and a second barrier layer formed in two different processes, leading to the different characteristics between the two barrier layers. The first barrier layer with higher conformity is deposited on the side surface of the opening for the cell contact, and the second barrier layer with lower resistivity is deposited on the bottom surface of the opening. The conductive layer of the cell contact may uniformly form on the first barrier layer and the second barrier layer to prevent from forming seam in the cell contact, thereby improving the reliability of the memory device. The second barrier layer directly contacts the source/drain region and the conductive layer to reduce the resistivity of the conductive path between the cell contact and the source/drain region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a gate structure on a substrate;
a source/drain region in the substrate;
a dielectric layer covering the substrate and the gate structure; and
a cell contact adjacent to the gate structure, wherein the cell contact comprises:
a conductive layer;
a first barrier layer on a sidewall of the conductive layer; and
a second barrier layer on a bottom surface of the conductive layer, wherein the second barrier layer directly contacts the first barrier layer and the source/drain region, and a second resistivity of the second barrier layer is lower than a first resistivity of the first barrier layer.

2. The memory device of claim 1, wherein the first barrier layer and the second barrier layer collectively surround the conductive layer to separate the conductive layer from the dielectric layer and the substrate.

3. The memory device of claim 1, wherein a first compactness of the first barrier layer is higher than a second compactness of the second barrier layer.

4. The memory device of claim 1, wherein a first thickness of the first barrier layer is equal to a second thickness of the second barrier layer.

5. The memory device of claim 1, wherein a first thickness of the first barrier layer is smaller than or equal to 20 nm.

6. The memory device of claim 1, wherein the first barrier layer and the second barrier layer comprise a same composition.

7. The memory device of claim 1, wherein the first barrier layer comprises TiN, SiN, SiO₂, or combinations thereof.

8. The memory device of claim 1, further comprising:
a third barrier layer on a top surface of the dielectric layer, wherein the conductive layer extends onto the third barrier layer, and a third resistivity of the third barrier layer is lower than the first resistivity of the first barrier layer.

9. The memory device of claim 8, wherein the third barrier layer directly contacts the first barrier layer.

10. The memory device of claim 8, wherein a side surface of the third barrier layer is coplanar with a side surface of the first barrier layer.

11. The memory device of claim 8, wherein the third resistivity of the third barrier layer is equal to the second resistivity of the second barrier layer.

12. The memory device of claim 1, wherein the first barrier layer extends into the source/drain region, and wherein the second barrier layer is lower than a top surface of the substrate.

13. The memory device of claim 1, wherein the first barrier layer comprises a material different from that of the dielectric layer.

14. A method of forming a memory device, comprising:
providing a gate structure on a substrate and a dielectric layer covering the gate structure;
forming an opening through the dielectric layer, wherein the opening exposes a source/drain region in the substrate;
depositing a first barrier layer in the opening and on the dielectric layer by a first process;
removing a first portion of the first barrier layer on a bottom surface of the opening, wherein a second portion of the first barrier layer is remained on a side surface of the opening;
depositing a second barrier layer on the bottom surface of the opening by a second process, wherein the second barrier layer has a second resistivity different from a first resistivity of the first barrier layer; and
forming a conductive layer in the opening.

15. The method of claim 14, wherein the first process is advanced sequential flow deposition, and the second process is chemical vapor deposition.

16. The method of claim 14, wherein the first barrier layer deposited by the first process has a first compactness different from a second compactness of the second barrier layer deposited by the second process.

17. The method of claim 14, wherein removing the first barrier layer further comprises removing a third portion of the first barrier layer on a top surface of the dielectric layer.

18. The method of claim 14, wherein depositing the second barrier layer on the bottom surface of the opening comprises directly depositing the second barrier layer onto the source/drain region exposed by the opening.

19. The method of claim 14, wherein after depositing the second barrier layer, the first barrier layer and the second barrier layer collectively cover the side surface and the bottom surface of the opening.

20. The method of claim 14, wherein after depositing the second barrier layer, the first barrier layer is exposed in the opening.
